(19) United States
(12) Patent Application Publication
(10) Pub. No.: US 2026/0190262 A1
(43) Pub. Date: Jul. 2, 2026

(54) A RADIO EQUIPMENT HOUSING, INSTALLATION AND ASSEMBLY

(71) Applicant: COMMUNICATIONS INFRASTRUCTURE NETWORKS LTD., London (GB)

(72) Inventors: Ashley SMATT, London (GB); Ben BLOOMFIELD, Baslow (GB); Rod WHITE, Frenchay (GB); Phil SHEPPARD, Maidenhead (GB); Austin OWENS, Leominster (GB); Stuart HEDDERLY, Nottingham (GB)

(21) Appl. No.: 19/116,118

(22) PCT Filed: Sep. 20, 2024
(86) PCT No.: PCT/GB2024/052449

§ 371 Date: Mar. 27, 2025

(30) Foreign Application Priority Data
Sep. 21, 2023 (GB) 2314513.9

(51) Int. Cl. H05K 5/02; H01Q 1/42; H04Q 1/02

(52) U.S. Cl. CPC H05K 5/0286; H01Q 1/42; H04Q 1/02; H05K 5/0204

(57) ABSTRACT

A radio equipment housing for electronic communications devices, comprising an enclosure having a landlord entryway and an operator entryway, each entryway having a door arranged to be closable over the respective entryway; a radome arranged to cover the enclosure; a plurality of operator equipment cabinets, individually accessible via the operator entryway and arranged within a first volume of the enclosure; a plurality of operator provision panels, accessible via the operator entryway and arranged within a second volume of the enclosure; an electrical supply panel, accessible via the landlord entryway and arranged within a third volume of the enclosure; and, at least one telecommunications antenna positioned in a roof space covered by the radome and connectable to the operator telecommunications equipment. Also disclosed is a radio equipment installation and a radio equipment assembly, each for providing a telecommunications network.

### FIELD OF THE INVENTION

This invention relates to a radio equipment housing for electronic communications devices, a radio equipment installation for providing a telecommunications network and a radio equipment assembly also for providing a telecommunications network.

### BACKGROUND

Modern-day society expects to have reliable wireless communication and high-speed data connectivity on demand. This increased demand brings with it a need for increased numbers of coupled antennas, radio units and baseband units along with demand for more effective and efficiently deployable solutions.

One source of complexity in bringing connectivity to the public is that there are many telecommunications operators competing to provide this connectivity and this leads to ever-increasing numbers of electronic communications devices installed in metropolitan areas.

In an attempt to be inobtrusive, antennas are often mounted externally to existing street furniture, such as to streetlamps/lampposts, telephone posts, bus shelters or buildings. To facilitate such external mountings, the equipment needs to be small and light weight and so typical installations support just one spectrum band for a single operator. This approach therefore leads to further proliferation of installations to the extent that the benefits of unobtrusiveness are lost.

Another approach is to install electronic communications devices inside closed housings on the side of streets. These housings contain the required baseband units for coupling to an externally mounted antenna array. However, as competition between telecommunications operators grows, and as the various devices are incrementally upgraded or replaced, the housings become increasingly unwieldly as they are overfilled with equipment and lack any consistent organisation.

### SUMMARY OF THE INVENTION

According to a first aspect of the invention there is provided a radio equipment housing for electronic communications devices, comprising:
one or more wall portions defining an enclosure having a landlord entryway and an operator entryway, each entryway having a door arranged to be closable over the respective entryway;
a radome arranged to cover the enclosure;
a plurality of operator equipment cabinets, individually accessible via the operator entryway and arranged within a first volume of the enclosure, each cabinet configured to receive operator telecommunications equipment therein;
a plurality of operator provision panels, accessible via the operator entryway and arranged within a second volume of the enclosure, each provision panel holding one or more provision ports for providing electrical connections for operator telecommunications equipment housed within a respective adjacent operator equipment cabinet;
an electrical supply panel, accessible via the landlord entryway and arranged within a third volume of the enclosure, for supplying power to the provision ports of the provision panels; and,
at least one telecommunications antenna positioned in a roof space covered by the radome and connectable to the operator telecommunications equipment.

By means of the invention, a radio equipment housing (or “housing”) is provided with a landlord entryway and an operator entryway, which may be considered as entryways for use by one or more landlords and one or more operators respectively. A landlord may be a person that owns and/or manages the housing, or a person associated with a party that owns and/or manages the housing. From hereon, “landlord” will be understood as referring equally to either a specific person owning the housing or a person associated with a party owning the housing. Further, it will be appreciated that the term “landlord” is not intended in a legal sense with respect to property law, but rather as a descriptive label indicating the possible circumstances of a user of the housing, particularly one having access to the landlord entryway.

The landlord may let, sell, grant, act as licensor or otherwise provide access to the housing to one or more operators. In particular, the landlord may allocate one or more operator equipment cabinets and operator provision panels to a particular operator in addition to the ability to access the housing via the operator entryway. The landlord may also provide authorisation to use certain equipment within the housing, such as the at least one telecommunications antenna within the roof space of the housing.

Accordingly, an operator is a person that may rent, buy, accept, act as licensee or otherwise obtain rights to use the housing from the landlord, or is a person associated with a party that may do so. In that sense, an “operator” may be considered as sharing similar circumstances to a tenant of a property. Therefore, in the context of this application, the terms “operator” and “tenant” may be used interchangeably with the understanding that the term “tenant” is not intended in a legal sense with respect to property law.

From hereon, the terms “operator” and/or “tenant” will be understood as referring equally to either a specific person with rights to use the housing or a person associated with a party owning such rights.

For example, the operator may be a telecommunications operator providing wireless communication and high-speed data connectivity to members of the public.

The separation of the landlord and operator entryways provides a landlord with a means of limiting access available to one or more operators. For example, there may be equipment within the housing that operators do not require access to in order to install and operate their own electronic communications devices. Such equipment may include equipment relating to the provision of electrical supply or environment control. Accordingly, the separation of the landlord and operator entryways represents a first means of organising the housing and reducing the likelihood of a single operator's activities negatively impacting the overall housing and/or ‘neighbour’ operators.

The plurality of operator equipment cabinets and respective operator provision panels allow for allocation of clearly defined spaces to be used by a particular operator. Each cabinet is configured to receive operator telecommunications equipment therein. The cabinets may all be the same size or may be a variety of sizes to cater for the needs of one or more operators. Further, operators may be provided with access to just one cabinet or more than one cabinet depending on their requirements.

Each provision panel holds one or more provision ports for providing electrical connections for operator telecommunications equipment housed within a respective adjacent operator equipment cabinet. In other words, each provisional panel is associated with, and configured for, an adjacent cabinet, meaning that cables extending from each provision panel to the respective cabinet may travel a direct path with little to no interference or tangling with other cables.

The electrical supply panel, which supplies electrical power to the plurality of provision ports, is accessible via the landlord entryway and may not be accessible via the operator entryway. This means that the landlord has control over the electrical power supply to the various operators' telecommunications equipment and prevents aa operator from inadvertently adjusting the electrical power supply to a neighbouring operator's telecommunications equipment. For example, it may not be possible for an operator to accidentally knock a switch that turns off power to a neighbouring operator's provision panel. Also, if a particular operator stops using the housing (either permanently or temporarily), it is simple for the landlord to turn off electrical supply to any telecommunications equipment left in the operator's equipment cabinet so that electrical power is not wasted.

In some instances, the landlord and one or more operators may be the same party or may be separate individuals associated with the same party. For example, the landlord may be a telecommunications operator that uses one telecommunications equipment cabinet and lets out one or more further telecommunications equipment cabinet for use by one or more other telecommunications operators. Nevertheless, the organisation of the housing's contents into distinct volumes within the housing provides many, if not all, of the same benefits when in use in such instances.

In some embodiments of the invention, the operator equipment cabinets may be vertically spaced in a stacked arrangement within the first volume. In such embodiments, the operator provision panels may be vertically spaced in a stacked arrangement within the second volume, each operator provision panel arranged in substantially the same plane as the respective adjacent operator equipment cabinet.

This vertical spacing of the operator equipment cabinets and provision panels means that there will be little or no reason for a particular operator to introduce telecommunications equipment to the housing that is spaced apart across different levels with interconnecting cables extending between them. The vertical spacing therefore allows for improved organisation of space within the housing and reduces or eliminates confusion caused by randomly positioned telecommunications equipment and tangled cables.

In some embodiments of the invention, the electrical supply panel may comprise a plurality of operator supply regions, each operator supply region configured to supply power to a respective provision panel. This allows the landlord to organise the landlord-accessible contents of the housing to correspond to the operator-accessible contents, thereby improving the ease with which the housing may be organised.

In further embodiments of the invention, the radio equipment housing may further comprise one or more operator closures, each operator closure arranged to be independently closable over:
one or more operator equipment cabinets;
one or more operator provision panels; or,
one or more operator equipment cabinets and the respective one or more operator provision panels.

Accordingly, when an operator accesses the housing, they may open only their own closure. This reduces the likelihood of confusion between similar telecommunication equipment owned by different operators and allows an operator to easily focus only on their own telecommunications equipment.

Furthermore, the, or each, operator closure may be independently lockable and unlockable. This provides each operator with privacy over their telecommunications equipment and prevents tampering (either accidentally or on purpose).

In embodiments of the invention, at least one of the one or more wall portions may comprise an intake vent arrangement.

The intake vent arrangement may comprise a filter assembly for removably receiving one or more air filters. The air filters may be configured to remove particulates from the air that may enter and build up over time, thereby reducing cooling efficiency and potentially causing damage to the telecommunications equipment. The air filters may additionally or alternatively be configured to remove vapours, such as water vapour, from the air before it enters one or more operator equipment cabinets, thereby reducing the likelihood of water damage to telecommunications equipment. This may be particularly beneficial if the housing is used in humid climates.

Heat may be generated within the housing by various telecommunications equipment operating at the same time. Therefore, providing ventilation through the housing may be beneficial to prevent the housing from overheating.

The term “overheating” may be considered as referring to a situation when the temperature in the housing undesirably raises above a particular temperature. The particular temperature associated with overheating may represent a temperature difference with the surrounding ambient temperate (e.g. it may be undesirable for the temperature inside the housing to raise more than 10 degrees above the surrounding ambient temperature. Alternatively, the particular temperature associated with overheating may be a temperature above which the functionality of telecommunications equipment may be negatively affected (e.g. some telecommunications equipment may be detrimentally affected by temperatures above 35° C.).

In some embodiments of the invention, each operator equipment cabinet may comprise an air inlet and an air outlet. The radio equipment housing may comprise a fluid movement device (e.g. a fan) arranged proximally to one or more air inlets or air outlets and operable to move air through the respective one or more operator equipment cabinets. The air inlet and air outlet may be arranged such that operation of the one or more fluid movement device generates a crossflow of air through the respective one or more operator equipment cabinets.

Operator equipment cabinets may comprise telecommunications equipment which may be among the primary generators of heat within the housing and may also benefit most from cooling to ensure proper functionality. Accordingly, providing a crossflow of air through one or more operator equipment cabinets can be beneficial both for cooling the telecommunications equipment inside as well as controlling the overall temperature inside the housing.

The fluid movement device may be accessible via the landlord entryway while being arranged to remove air from the respective one or more operator equipment cabinets. This allows the landlord to have control over the fluid movement device's operation. For example, it may be desirable to reduce or stop operation of a fluid movement device if the respective operator equipment cabinet is unused. Conversely, it may be desirable to increase operation of a fluid movement device if the respective operator equipment cabinet is heavily used.

A landlord may alternatively attach a blanking plate to an air inlet or outlet of an operator equipment cabinet in order to entirely prevent air passing through it. This may be useful if one or more operator equipment cabinet are unused as those cabinets can be blocked so that air passes through only the operator equipment cabinet(s) in use.

The radio equipment housing may comprise a plurality of fluid movement devices with one or more fluid movement devices arranged to generate a cross-flow of air through any one or more of a plurality of operator equipment cabinet.

Each air inlet of the equipment cabinet may be arranged proximally to the intake vent arrangement. This may allow air from outside of the housing to be drawn directly through one or more operator equipment cabinets. This may be particularly beneficial if the housing is situated in an environment where the ambient air temperature is typically in the range of an optimal operating temperature of telecommunications equipment.

In some embodiments of the invention, the radio equipment housing may further comprise an exhaust vent arrangement allowing air that has travelled through one or more operator equipment cabinets to exit the housing. This prevents warm air building up in the radio equipment housing increasing the internal temperature and reducing the efficacy of the intake vent arrangement and one or more fluid movement devices.

In some embodiments of the invention, the radio equipment housing may further comprise an exhaust control device coupled to the exhaust vent arrangement and configured to control the rate that air exits the radio equipment housing.

In some situations it may be beneficial to retain some heat in the radio equipment housing. For example, if the outside temperature is particularly cold, it may be beneficial to maintain a warmer temperature inside the housing so that electrical devices are operating in optimal conditions. Further, maintaining temperature above a certain level will protect against condensation forming on internal surfaces of the housing. Accordingly, the exhaust control device may be configured to slow the rate of air exhausted from the housing so that warm air is retained sufficiently to maintain an internal temperature within a predetermined range. For example, between 0° and 30°, preferably between 5° and 25°, more preferably between 10° and 20°.

In some embodiments of the invention, the one or more fluid movement devices and the exhaust control device may be operable to maintain an internal pressure within the radio equipment housing that is greater than an external pressure outside of the radio equipment housing. It will be appreciated that the internal pressure may be maintained as greater than the external pressure when the doors are closed. When one or both doors are open, operation of the one or more fluid movement devices and the exhaust control device to maintain the desired internal pressure may be paused until both doors are closed once more.

In this context, the one or more fluid movement devices and the exhaust control device may be considered as a positive input ventilation (PIV) system for the radio equipment housing.

By controlling airflow in and out of the radio equipment housing so that the internal pressure is greater than the external pressure, unintended inflow of air through any small gaps that exist in the structure of the radio equipment housing will be prevented. This means that the only air entering the radio equipment housing (unless one or both doors are opened) is air that enters through air filters within the intake vent arrangement. Thus, the housing is protected from unfiltered air.

The connector channel may allow for connectors, such as data and/or power cables, to be neatly positioned and, optionally, concealed while extending from the plurality of operator equipment cabinets to the roof space. This may reduce the degree to which connectors extend along random paths that may be obstructive to users of the housing.

In embodiments of the invention, one or more of the plurality of operator equipment cabinets, plurality of operator provision panels, electrical supply panel and connector channel form a rigid three-dimensional structure extending across an internal dimension of the enclosure, thereby rigidifying the enclosure.

One or more of the plurality of operator equipment cabinets, plurality of operator provision panels, electrical supply panel and connector channel may have a rigid construction by virtue of the various walls and shelves that are fixed together to provide the different cabinets, panels and/or channels. On the other hand, the one or more walls that define the enclosure of the housing may lack a degree of rigidity due to the size of the one or more walls, unless proper bracing is provided. There may be various suitable methods of bracing the one or more walls of the housing, such as providing a network of supportive struts. However, fixing a rigid three-dimensional structure (formed from one or more of one or more of the plurality of operator equipment cabinets, plurality of operator provision panels, electrical supply panel and connector channel) to the one or more walls of the housing may provide the same rigidifying effect and reduces or avoids the requirement for additional components being added to the housing. This may therefore reduce the cost and weight of the housing and may also save space within the housing.

In some embodiments of the invention, the landlord entryway and the operator entryway may be arranged on substantially opposing sides of the enclosure. This provides a clear demarcation between the areas accessible by different parties and reduces the likelihood of confusion between equipment that may be accessed by a operator and equipment that should only be accessed by the landlord.

For example, the one or more wall portions may comprise four wall portions including a first wall portion, comprising the landlord entryway, and a second wall portion, comprising the operator entryway, arranged substantially opposite the first wall portion. In other words, the one or more wall portions may form an enclosure with a rectangular cross-section (or a cross-section with a similar quadrilateral shape such as parallelogram or rhombus), wherein the landlord and operator entryways are on opposing sides.

In embodiments of the invention, the roof space may be accessible via the landlord entryway, operator entryway or both.

As the roof space houses at least one telecommunications antenna, it may be beneficial to allow both the landlord and the operator to readily access the roof space. For example, a landlord may require access to connect electrical supply cables to the at least one telecommunications antenna so that it is provided with a sufficient and correct electrical supply. Meanwhile, a operator may also require access to connect data transfer cables to the at least one telecommunications antenna from the operator's telecommunications equipment.

Further, both a landlord and an operator may require access to the roof space to install, and connect electrical supply and data transfer cables to, equipment in the roof space other than the at least one telecommunications antenna. For example, a landlord or an operator may benefit from installing a Wi-Fi® router in the radio equipment housing and an optimal location for such a Wi-Fi® router may be the roof space by virtue of the additional height and the reduction of surrounding electronic equipment that may interfere with a Wi-Fi® signal.

In embodiments of the invention, the radio equipment housing may further comprise a connector channel, arranged within a fourth volume of the enclosure, providing space for one or more connectors to extend at least partially from the plurality of operator equipment cabinets and/or the plurality of operator provision panels to, at least, the antenna, the connector channel comprising a channel accessway suitable for access of an operator via the operator entryway.

According to a second aspect of the invention there is provided a radio equipment housing for electronic communications devices, comprising:
four wall portions defining an enclosure having a landlord entryway and an operator entryway located substantially opposite to the landlord entryway, each entryway having a door arranged to be closable over the respective entryway;
a radome arranged to cover the enclosure;
a plurality of vertically spaced operator equipment cabinets, individually accessible via the operator entryway and arranged within a first volume of the enclosure, each cabinet configured to receive operator telecommunications equipment therein;
a plurality of vertically spaced operator provision panels, accessible via the operator entryway and arranged within a second volume of the enclosure, each provision panel holding one or more provision ports for providing electrical connections for operator telecommunications equipment housed within a respective adjacent operator equipment cabinet;
an electrical supply panel, accessible via the landlord entryway and arranged within a third volume of the enclosure, for supplying power to the provision ports of the provision panels; and,
at least one telecommunications antenna positioned in a roof space covered by the radome and connectable to the operator telecommunications equipment.

The features and advantages of the first aspect of the invention and its embodiments apply mutatis mutandis to the second aspect of the invention and its embodiments.

The radio equipment housing (or ‘housing’) may have a substantially quadrilateral cross-sectional shape defined by the four wall portions. Preferably, the housing may have a substantially rectangular cross-sectional shape defined by the four wall portions. The cross-sectional shape may be considered as a rectangle or other quadrilateral shape despite having minor modifications to improve the aesthetics of the housing. For example, the housing may have rounded or chamfered corners or convex or concave walls and still be considered as having a substantially rectangular or quadrilateral cross-sectional shape.

According to a third aspect of the invention there is provided a radio equipment installation for providing a telecommunications network, comprising a radio equipment housing installed at ground level, the radio equipment housing including:
at least one set of radios; the, or each, set of radios:
comprising at least one 4G or 5G radio and a set of connectors for connecting the radios to a telecommunications antenna, and
configured to be capable of, in use, providing an effective isotropic radiated power (EIRP) of substantially 100 W; and
a telecommunications antenna configured to operate in a plurality of frequency bands and simultaneously transmit signals from a plurality of sets of radios, the telecommunications antenna comprising a plurality of ports, wherein the at least one set of radios is connected to the telecommunications antenna via a respective at least one set of ports of the plurality of ports,
wherein the radio equipment installation is configured such that the radio equipment housing holds the telecommunications antenna at least 2.5 m above ground level and such that the radio equipment housing is located in its environment to provide a physical isolation zone extending radially from an outer surface of the telecommunications antenna by at least 1 m.

The features and advantages of the first and second aspects of the invention and their embodiments apply mutatis mutandis to the third aspect of the invention and its embodiments.

In some embodiments, the radio equipment housing houses the at least one set of radios and the telecommunications antenna.

It will be appreciated that “ground level” is to be understood as the level of an area of ground such as a road, pavement, sidewalk, pedestrianised area, park, carpark or train platform. In some embodiments, the radio equipment installation (or “installation”) be located in a public space or space accessible by the public such that the housing may be considered as “installed at ground level in a public space” or “installed at ground level in a publicly accessible environment”. In other embodiments, the installation may be located in a private location. For example, the installation may be located in a military base to provide a telecommunications network for that base.

It is anticipated that the radio equipment housing would typically be installed in outdoor spaces. However, in some instances, the housing may be installed in indoor spaces, particularly large indoor spaces that may have high densities of people requiring high quality 4G/5G access, such as arenas, stadiums, airports and train/subway stations.

Effective isotropic radiated power (EIRP) may be calculated as follows:

$$EIRP = PTx + G - L$$

Where:
PTx is Transmitter Power (in Watts)
G is Antenna Gain (in dBi)
L is system losses (in dB)

As the EIRP that is provided to a telecommunications antenna increases, the levels of radiation emitted by the antenna also increase.

An antenna provided with an EIRP of 100 W will generate a field of potentially harmful radiation extending radially outward. In reality, the field of radiation extends irregularly with the average extent of potentially harmful radiation extending much less than 1 m, but there may be some spikes in certain directions that stretch as far as 1 m. Accordingly, the International Commission on Non-Ionizing Radiation Protection (ICNIRP) determines that an antenna provided with an EIRP of 100 W should operate with an Exclusion Zone extending 1 m radially outward from the antenna, whereby the Exclusion Zone should not be entered.

Also, known radio and antenna devices suitable for an EIRP of 100 W are large and heavy to an extent that makes them very difficult to install in in publicly accessible spaces whilst also sufficiently spaced away from the reach of the public (i.e. elevated positions, such as mounted on lampposts or building facades).

For these reasons, radio and antenna devices suitable for an EIRP of 100 W are not currently installed in publicly accessible spaces.

A radio equipment installation according to a third aspect of the invention provides a solution to these issues and therefore enables installation of radios configured to provide an EIRP of 100 W in a publicly accessible setting. This is achieved through configuration of the radio equipment installation such that the radio equipment housing holds the telecommunications antenna at least 2.5 m above ground level (i.e. safely above head height) and such that a physical isolation zone extends radially from an outer surface of the at least one telecommunications antenna. In particular, the physical isolation zone extends radially from an outer surface of the at least one telecommunications antenna by at least 1 m, sufficient to prevent the public inadvertently entering the ICNIRP Exclusion Zone for an antenna provided with an EIRP of 100 W.

The physical isolation zone is to be understood as a zone that is physically isolated from inadvertent physical access by the public when the radio equipment housing is deployed in a publicly accessible environment as a radio equipment installation. It will be appreciated that the provision of the physical isolation zone is dependent on the location of the radio equipment housing within the immediate environment it is installed within and that a variety of considerations are therefore required when installing the radio equipment housing as part of a radio equipment installation. For example, the radio equipment housing may be set back from a nearby road to ensure that an occupant of a bus, lorry or other tall vehicle stopping at the side of the road alongside the radio equipment housing would not enter the physical isolation zone. In another example, the housing may be positioned away from street furniture (such as benches, stairs or bins) that could be climbed by a member of the public and allow that person to enter the physical isolation zone.

The radio equipment housing may comprise a physical barrier preventing access to the physical isolation zone. However, this is not necessarily the case. It will, therefore, be appreciated that climbing of the radio equipment housing while it is operational is an incorrect and unintended use of the radio equipment housing. Accordingly, although a member of the public may be able to climb the radio equipment housing and enter the physical isolation zone, this misuse of the housing should not be considered as impacting the scope of the claims presented herein.

In some embodiments, the physical isolation zone may extend radially from the telecommunications antenna by at least 1.25 m; preferably by at least 1.5 m. A physical isolation zone extending at least 1.25 m from is sufficient to prevent the public inadvertently entering the ICNIRP Exclusion Zone for an antenna provided with an EIRP of 200 W. A physical isolation zone extending at least 1.5 m from is sufficient to prevent the public inadvertently entering the ICNIRP Exclusion Zone for an antenna provided with an EIRP of 300 W.

An EIRP greater than 100 W, such as 200 W or 300 W, may be provided by a single set of radios or by a plurality of sets of radios. For example, two sets of radios that each provide 100 W to the telecommunications antenna will cause a total EIRP of 200 W to be provided to the telecommunications antenna.

In one or more embodiments of the invention, the at least one set of radios comprises up to three sets of radios. The up to three sets of radios may be configured to be capable of, in use, providing an EIRP of substantially 300 W. In such embodiments, the physical isolation zone may extend at least 1.5 m.

In some embodiments of the invention, the physical isolation zone extends radially outwardly and horizontally from the at least one telecommunications antenna. The orientation of the physical isolation zone is dependent on the orientation of the ICNIRP Exclusion Zone, which is, in turn, dependent on the orientation of the telecommunications antenna. Preferably, the telecommunications antenna is oriented such that physical isolation zone extends horizontally, i.e. parallel to the ground. In embodiments in which the physical isolation zone does not extend horizontally, the telecommunications antenna may be held higher than 2.5 m above the ground so that the physical isolation zone does not drop below 2.5 m above the ground.

In further embodiments of the invention, the, or each, set of ports comprises at least 8 ports connected to an associated set of radios. This may facilitate suitable connection with the/each respective set of radios, particularly if the/each set of radios includes a plurality of radios. Furthermore, the telecommunications antenna may comprise three sets of ports. Accordingly, in some examples, the telecommunications antenna may comprise at least 24 ports.

In one or more embodiments of the invention, the installation may further comprise at least one radio unit installed remotely to the radio equipment housing. The at least one radio unit may be connected to the radio equipment housing via a cabled connection.

In some embodiments of the invention, the at least one radio unit may be mounted on street furniture.

In additional embodiments of the invention, the installation may further comprise at least one hybrid fibre optic cable extending from the radio equipment housing to the at least one radio unit and configured to supply data and power from the radio equipment housing to the at least one radio unit. The at least one hybrid fibre optic cable may connect the radio equipment housing to the at least one radio unit.

In one or more embodiments of the invention, the installation may further comprise at least one base band unit. The at least one base band unit may be housed within the radio equipment housing.

In further embodiments of the invention, the radio equipment housing may be configured according the first aspect of the invention or the second aspect of the invention.

According to a fourth aspect of the invention there is provided a method of installing radio equipment including at least one set of radios and a telecommunications antenna. The, or each, set of radios comprises at least one 4G or 5G radio and a set of connectors for connecting the radios to the telecommunications antenna, and is configured to be capable of, in use, providing an effective isotropic radiated power (EIRP) of substantially 100 W. The telecommunications antenna is configured to operate in a plurality of frequency bands and simultaneously transmit signals from a plurality of sets of radios. The telecommunications antenna comprises a plurality of ports, wherein the at least one set of radios is connected to the telecommunications antenna via a respective at least one set of ports of the plurality of ports. The method comprises housing the at least one set of radios and the telecommunications antenna within a radio equipment housing; and installing the radio equipment housing at ground level such that the radio equipment housing holds the telecommunications antenna at least 2.5 m above ground level and such that the radio equipment housing is located in its environment to provide a physical isolation zone extending radially from an outer surface of the telecommunications antenna by at least 1 m.

The features and advantages of the preceding aspects of the invention and their embodiments apply mutatis mutandis to the fourth aspect of the invention and its embodiments.

In some embodiments, installing the radio equipment housing comprises locating the radio equipment housing in its environment to provide a physical isolation zone extending radially from an outer surface of the telecommunications antenna by at least 1.25 m; preferably by at least 1.5 m.

In one or more embodiments, the method may further comprise installing at least one radio unit remotely to the radio equipment housing. Installing the at least one radio unit may comprise installing the at least one radio unit on street furniture.

In additional embodiments, the method may further comprise installing at least one hybrid fibre optic cable connecting the radio equipment housing to the at least one radio unit. The at least one hybrid fibre optic cable may be configured to supply data and power from the radio equipment housing to the at least one radio unit.

In some embodiments, the method may further comprise housing at least one base band unit within the radio equipment housing.

According to a fifth aspect of the invention there is provided a radio equipment assembly for providing a telecommunications network, comprising a radio equipment housing installed at ground level and at least one radio unit installed remotely to the radio equipment housing, wherein the at least one radio unit is connected to the radio equipment housing to receive data, power or both from the radio equipment housing, and wherein the radio equipment housing includes:
at least one set of radios; the, or each, set of radios comprising at least one 4G or 5G radio and a set of connectors for connecting the radios to a telecommunications antenna; and
a telecommunications antenna configured to operate in a plurality of frequency bands and simultaneously transmit signals from a plurality of sets of radios, the telecommunications antenna comprising a plurality of ports, wherein the at least one set of radios is connected to the telecommunications antenna via a respective at least one set of ports of the plurality of ports.

The features and advantages of the preceding aspects of the invention and their embodiments apply mutatis mutandis to the fifth aspect of the invention and its embodiments.

By means of the invention, a radio equipment assembly (or “assembly”) may provide a telecommunications network wherein a radio equipment housing acts as a central hub while one or more remotely installed radio units expand the coverage of the telecommunications network in a flexible manner that may be optimised for each application (based on variables such as local topography, building structures, population density, traffic/footfall, etc.).

In some embodiments of the invention, the at least one radio unit may be mounted on street furniture. Non-exclusive, examples of suitable street furniture include lampposts road signs, tourist information signs, bus or tram stop shelters, gazebos or pagodas. In further embodiments, one or mor radio units may additionally or alternatively be mounted on larger structures such as retail kiosks, buildings and bridges. It will be appreciated that an assembly comprising a plurality of remotely installed radio units may comprise some radio units installed on street furniture and other radio units installed on other structures.

Known radio units are sometimes installed on existing street furniture, or other structures, to provide improved 4G and/or 5G connectivity in specific locations. Such radio unit installations may be referred to as micro cells or small cells. However, the positioning of such radio units is limited by access to a fibre optic data connection and/or a suitable power supply. This has stalled the deployment of small cells and micro cells across built-up areas such as dense city centres because the cost of installing the necessary underlying infrastructure on a per-unit basis is exorbitant.

The radio equipment assembly enables the installation of a single radio equipment housing in a central location which may have the capacity to transmit and receive data at very high speeds and/or transform high voltage alternating current (AC) to the low voltage direct current (DC) required by radio units. A simple cabled connection may then be provided to one or more radio units facilitating transfer of data and/or power without needing to install the same level of underlying infrastructure at each site that the radio units are installed.

In one or more embodiments invention, the radio equipment assembly may further comprise at least one hybrid fibre optic cable extending from the radio equipment housing to the at least one radio unit and configured to supply data and power from the radio equipment housing to the at least one radio unit. Thus, installation of only a single cable between the housing and each radio unit is required. The at least one hybrid fibre optic cable may connect the radio equipment housing to the at least one radio unit.

In some embodiments of the invention, the radio equipment assembly may comprise other components and/or devices. For example, the radio equipment assembly may further comprise at least one base band unit. The at least one base band unit may be housed within the radio equipment housing or may be stored remotely to the radio equipment housing.

In further embodiments of the invention, the at least one set of radios comprises up to three sets of radios. The up to three sets of radios may be configured to be capable of, in use, providing an EIRP of substantially 300 W.

In one or more embodiments invention, the, or each, set of ports in the telecommunications antenna may comprise at least 8 ports connected to an associated set of radios. The telecommunications antenna may comprise three sets of ports.

In some embodiments of the invention, the radio equipment housing is configured as a radio equipment housing according to the first aspect of the invention or the second aspect of the invention.

In further embodiments of the invention, the radio equipment housing is installed as a radio equipment installation according to the third aspect of the invention.

### BRIEF DESCRIPTION OF THE DRAWINGS

Preferred embodiments of the invention will now be described, by way of non-limiting examples, with reference to the accompanying drawings in which:

FIG. 1 is a plan-view illustration of a radio equipment housing;

FIG. 2a is a perspective-view illustration of an operator side of the radio equipment housing shown in FIG. 1, and FIG. 2b is a corresponding close-up view;

FIG. 3 is a perspective-view illustration of a landlord side of the radio equipment housing shown in FIG. 1;

FIG. 4a is a further perspective-view illustration of the landlord side of the radio equipment housing shown in FIG. 1, and FIG. 4b is a corresponding close-up view;

FIG. 5 is a cross-sectional-view illustration of the radio equipment housing shown in FIG. 1;

FIG. 6 is a schematic illustration of a radio equipment installation;

FIG. 7 is a schematic illustration of a radio equipment housing forming part of the radio equipment installation shown in FIG. 6;

FIG. 8 is a schematic illustration of a radio equipment assembly; and,

FIG. 9 is a schematic illustration of another radio equipment assembly.

### DETAILED DESCRIPTION

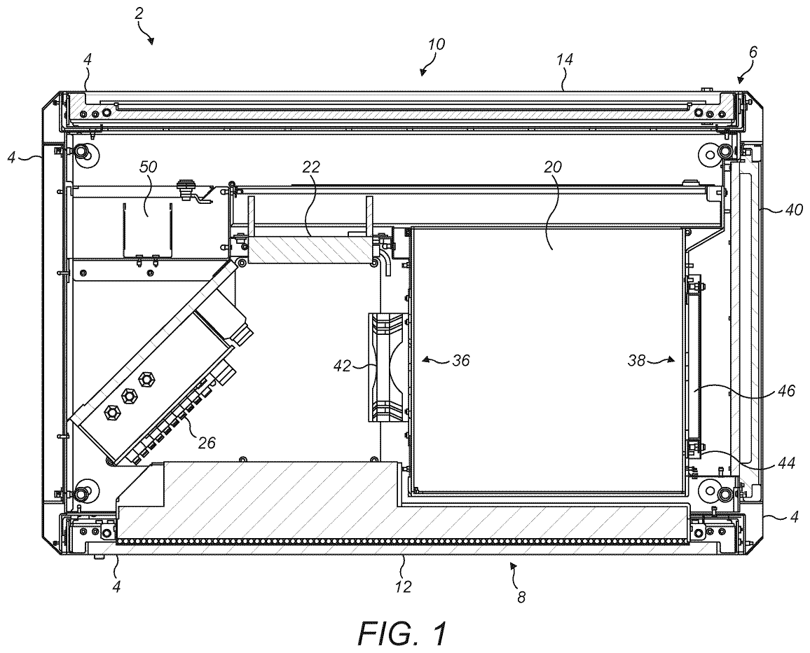

FIG. 1 shows an example embodiment of a radio equipment housing 2. The housing 2 comprises four wall portions 4 arranged in a substantially rectangular layout to define an enclosure 6.

In other embodiments, the four wall portions may be arranged in a different quadrilateral shape. In further embodiments, there may be a different number of wall portions arranged in any suitable shape to form an enclosure around internal components that are described below. For example, the housing may comprise a single wall portion that is curved to form an elliptically shaped enclosure, or the housing may comprise a plurality of wall portions arranged to define an enclosure shaped with a corresponding number of sides.

The enclosure 6 comprises a landlord entryway 8 and an operator entryway 10, each entryway having a door 12, 14 arranged to be closable over the respective entryway.

In this embodiment, the landlord entryway 8 and operator entryway 10 are arranged on substantially opposing sides of the housing 2/enclosure 6. More specifically, a first wall portion 4 comprises the landlord entryway 8 and a second wall portion 4 arranged substantially opposite the first wall portion 4 comprises the operator entryway 10. The side of the housing 2 having the landlord entryway 8 may be considered as the ‘landlord side’ and the side of the housing 2 having the operator entryway 10 may be considered as the ‘operator side’.

The housing 2 further comprises a plurality of operator equipment cabinets 20 and a comprises a plurality of operator provision panels 22, each of which are accessible via the operator entryway 10. The plurality of operator equipment cabinets 20 are arranged within a first volume of the enclosure 6 while the plurality of operator provision panels 22 are arranged within a second volume of the enclosure 6. In this embodiment, the plurality of operator equipment cabinets 20 and the plurality of operator provision panels 22 are vertically spaced in a stacked arrangement (i.e. above and/or below one another), hence only one operator equipment cabinet 20 and one operator provision panel is visible in FIG. 1.

The housing 2 also comprises an electrical supply panel 26, accessible via the landlord entryway 8 and arranged within a third volume of the enclosure 6.

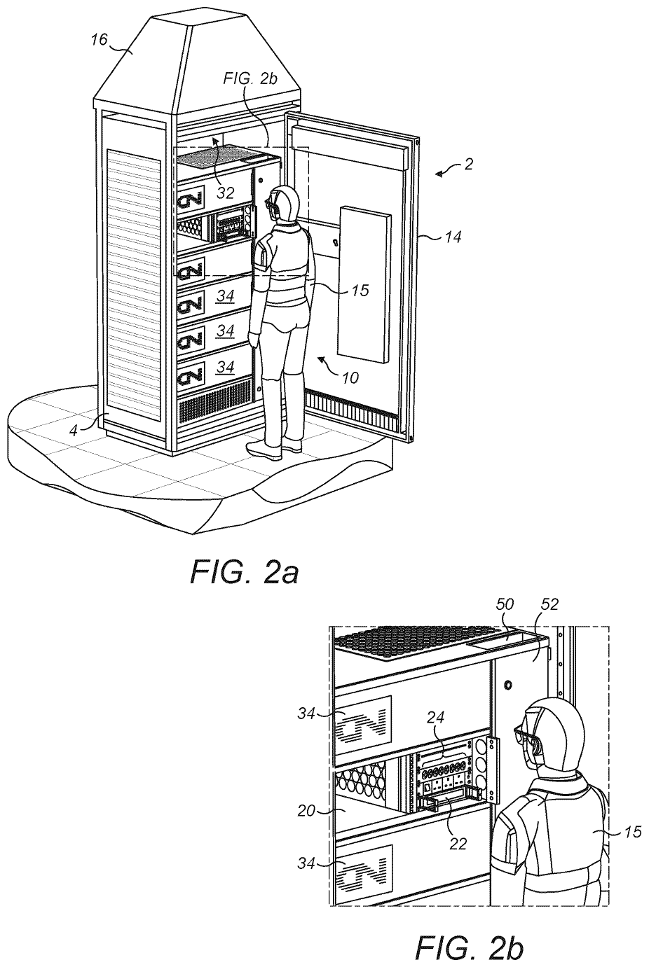

FIGS. 2a and 2b show the operator side of the housing 2 with the operator door 14 open to allow an operator 15 to access the contents of the operator side.

In this embodiment, the housing 2 further comprises a plurality of operator closures 34, each operator closure 34 arranged to be independently closable over both a specific operator equipment cabinet 20 and its respective operator provision panel 22. Each operator closure is independently lockable and unlockable.

Each cabinet 20 is configured to receive operator telecommunications equipment therein. Each provision panel 22 holds one or more provision ports 24 for providing electrical connections for operator telecommunications equipment housed within the adjacent operator equipment cabinet 20.

In other embodiments, each operator closure may be independently closable over just an operator equipment cabinet or just an operator provision panel. Furthermore, it is possible each operator equipment cabinet and each operator provision panel has its own operator closure. In further embodiments, an operator closure may be closable over more than one operator equipment cabinet, more than one operator provision panel or more than one operator equipment cabinet and operator provision panel combination.

In the present embodiment, the housing 2 comprises a total of six operator equipment cabinets 20 and a respective number of operator provision panels 22 and operator closures 34. A single operator 15 may have access to only a single operator equipment cabinet 20 and associated panel 22. Alternatively, a single operator 15 may have access to more than one operator equipment cabinet 20 and associated panel 22. For example, the housing 2 may be used by three operators 15, each having access to two operator equipment cabinets 20 and associated panels 22.

In some embodiments, a housing 2 may be used by a predetermined maximum number of different operators. For example, a housing 2 may be used by a maximum of three different operators. Such housings 2 may be configured with a respective number of operator equipment cabinets 20, operator provision panels 22 and/or operator closures 34.

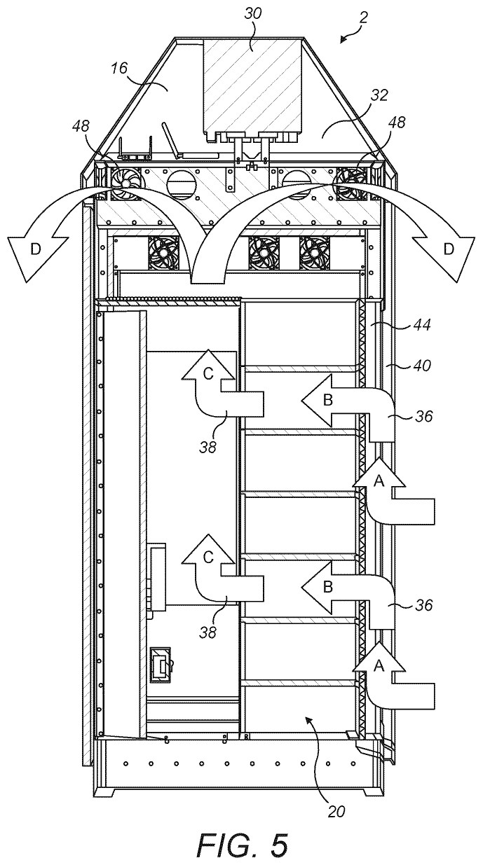

The housing 2 shown in FIGS. 2a and 2b further comprises a radome 16, arranged to cover the enclosure 16, and a telecommunications antenna 30 (see FIG. 5) positioned in a roof space 32 (see FIG. 5) covered by the radome 16. The roof space 32 is accessible via the operator entryway 10.

The housing 2 also comprises a connector channel 50, arranged within a fourth volume of the enclosure 6. The connector channel 50 provides space for one or more connectors to extend, at least partially, from the plurality of operator equipment cabinets 20 and/or the plurality of operator provision panels 22 to the telecommunications antenna 30 in the roof space 32. The connector channel 50 comprises a channel accessway suitable accessible by an operator 15 via the operator entryway 10. Further, in this embodiment, the connector channel 50 comprises a channel closure 52 closable over the channel accessway.

In use, an operator 15 may be granted the ability to open the operator door 14, the channel closure 52 and the one or more operator closures 34 that close over the operator equipment cabinet(s) and provision panel(s) that the specific operator owns or is ‘renting’ from the landlord of the housing 2. This access may be granted with the provision of suitable unlocking means (such as keys, codes or electronic signatures) configured for unlocking respective locks of the operator door 14, channel closure 52 and operator closure(s) 34.

With this access, the operator 15 may install telecommunications equipment (not shown) into an operator equipment cabinet 20. The operator 15 may provide power to the telecommunications equipment by connecting it to a provision port 24 in an adjacent operator provision panel 22. The operator 15 may also connect the telecommunications equipment to the telecommunications antenna 30 in the roof space 32 by extending suitable connectors/cables across to the connection channel 50 and up to the roof space 32.

The partitioning of the operator equipment cabinets 20, operator provision panels 22, connector channel 50 and roof space 32 enforces a degree of tidiness sufficient to ensure that the operator side of the housing 2 remains organised and easy to use. This is in contrast to known radio equipment housings which rapidly become disorganised and unwieldly due to various different operators applying random approaches to equipment and cable placement and management. Further, the independently closable and lockable operator closures 34 ensure that any operator accessing the radio equipment housing 2 can only access his/her own telecommunications equipment, providing each operator with privacy over their telecommunications equipment and preventing tampering (either accidentally or on purpose).

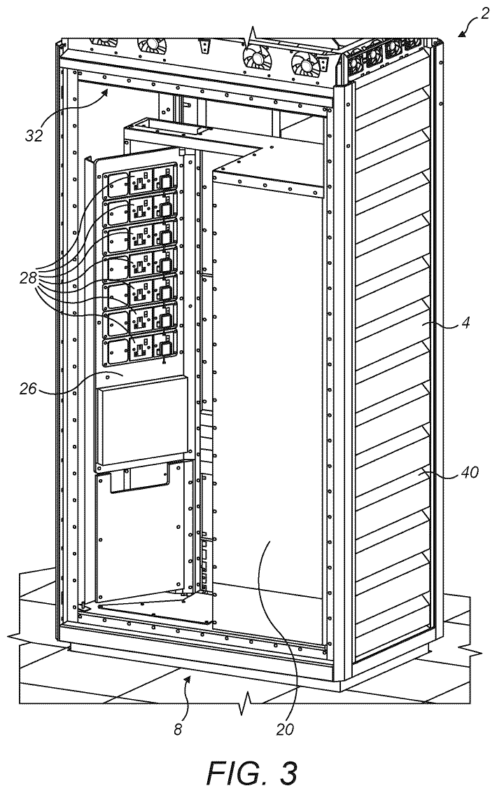

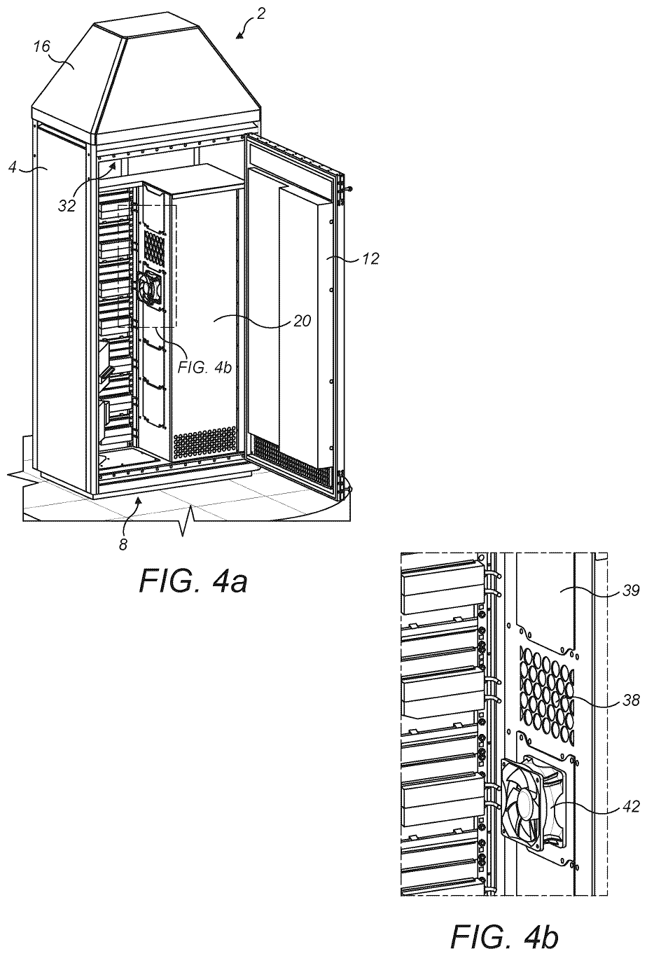

FIGS. 3, 4a and 4b each show the landlord side of the housing 2. In FIG. 3, the electrical supply panel 26 is particularly visible. In this embodiment, the electrical supply panel 26 is angled across the third volume so as to be easily accessible by a landlord standing outside of the housing 2 while also allowing space for the landlord to step into the housing 2, for example to shelter from bad weather. The angled orientation of the electrical supply panel 26 also allows ample space behind the panel to conceal cabling.

The electrical supply panel 26 is configured for supplying power to the provision ports 24 of the provision panels 22 accessible via the operator entryway 10. In this embodiment, the electrical supply panel 26 comprises a plurality of operator supply regions 28. For example, operator supply region may include one or more electrical plug sockets for supplying electricity from the electrical power grid (referred to as mains electricity in the UK) to a provision port.

The plurality of operator supply regions may include at least as many operator supply regions as there are operator equipment cabinets such that each operator supply region 28 may be configured to supply power to a respective provision panel 22. In some examples, each operator supply region 28 may be arranged in substantially the same plane as a respective operator equipment cabinet 20.

In use, a landlord will have access to provide or remove supply of power to any one of the operator provision panels 22. This provides the landlord with a suitable level of control over the usage of the housing 2. For example, the landlord may avoid wastage of energy that might otherwise occur if power was supplied to an operator provision panel that is no longer being actively used but remains connected to abandoned telecommunications equipment.

In this embodiment, the landlord will also have access to the roof space 32 via the landlord entryway 8. The landlord will therefore be able to access the telecommunications antenna 30 in case adjustment, maintenance or replacement is required.

FIG. 3 also shows that the wall portion adjacent to the plurality of operator equipment cabinets 20 comprises an intake vent arrangement 40 having vents that allow air into the housing 2 from the surrounding environment.

Referring now to FIGS. 4a and 4b, each operator equipment cabinet 20 comprises an air outlet 38. One or more air outlets 38 may be covered by a blanking plate 39 to prevent air moving through the respective one or more operator equipment cabinets 20. Alternatively, a fluid movement device 42 may be arranged proximally to one or more air outlets 38, the fluid movement device 42 operable to remove air from the respective one or more operator equipment cabinets 20. In this example, the fluid movement device 42 is a fan coupled directly to an air outlet 38 and configured to suck air through the operator equipment cabinet 20.

In other embodiments, one or more blanking plates 39 may cover one or more air inlets 36 rather than air outlets 38.

Similarly, one or more fluid movement devices 42 may be arranged proximally to the air inlets 36 rather than the air outlets 38. In such examples, the/each fluid movement device 42 would be positioned between the intake vent arrangement 40 and one or more air inlets 36 and configured to blow air through the respective one or more operator equipment cabinets 20.

FIG. 5 shows a cross-section of the housing 2. In addition to comprising an air outlet 38, each operator equipment cabinet 20 comprises an air inlet 36.

For simplicity, only two of the operator equipment cabinets 20 are annotated with respective air inlets and outlets 36, 38. However, it may be assumed each operator equipment cabinet 20 has both an air inlet 36 and an air outlet 38. One or more of the air outlets may be covered by a blanking plate 39 or a fluid movement device 42 (neither of which are shown in FIG. 5, but both are illustrated in FIG. 4b).

The intake vent arrangement 40 comprises further comprises a filter assembly 44 for removably receiving one or more air filters 46 (shown in FIG. 1). The air filters may, for example, remove particulates and/or moisture from air before it enters the operator equipment cabinets 20. In the present embodiment, the wall portion 4 covers the air filters and the wall portion 4 is removeable to allow removal and replacement of the air filters. In other embodiments, the air filters may be removeable in a cassette-like manner via the landlord entryway 8.

Arrows A, B, C, D represent the path of air through the housing 2 during typical operation (i.e. with the landlord and operator doors 12, 14 closed). One or more fluid movement devices (not shown) cause movement of air as follows:
a. air drawn into the housing from the surrounding environment through the intake vent arrangement 40;
b. air drawn into one or more operator equipment cabinets 20 from the intake vent arrangement 40;
c. air drawn out of the one or more operator equipment cabinets 20 and expelled into the third volume of the housing 2; and
d. air expelled from the housing via exhaust vent arrangement 47 (shown in FIGS. 4a) located towards the top of the housing 2 (proximal to the radome 16).

Telecommunications equipment operational inside the one or more operator equipment cabinets 20 will inherently generate heat and may be in danger of overheating if the temperature within the operator equipment housings 20 raises above a particular level.

Steps B and C, in particular, generates a crossflow of air through one or more operator equipment cabinets 20. As the air temperature outside housing 2 is most likely lower than the temperature inside the operator equipment cabinets 20, the crossflow of air will typically have a cooling effect.

The air that is expelled into the third volume of the housing 2 will have been heated by the operational telecommunications equipment and will therefore rise through the housing 2 until it is able to escape through an exhaust vent arrangement located towards the top of the housing 2.

In cold weather conditions, the fluid movement devices 42 may be set to a low air-speed setting as the low temperature of the outside air will have a large cooling effect. The fluid movement devices 42 may even be turned off entirely as movement of air caused by convection may result in sufficient cooling.

In hot weather conditions, the fluid movement devices 42 may be set to a much higher air speed as the hotter air will have a reduced cooling effect and it will therefore be necessary to replace air inside the housing 2 much faster so that the telecommunications equipment does not overheat.

In this embodiment of the invention, the radio equipment housing 2 further comprises an exhaust control device 48 coupled to the exhaust vent arrangement and configured to control the rate that air exits the housing 2. That is, the exhaust control device 48 controls the rate of step D.

More particularly, the exhaust control device 48 may be configured to slow the rate of air exhausted from the housing 2 so that warm air is retained sufficiently to maintain an internal temperature within a predetermined range. For example, between 0° and 30°, preferably between 5° and 25°, more preferably between 10° and 20°. This may be beneficial if, for example, the outside temperature is particularly cold and maintenance of a warmer temperature is required so that electrical devices in the housing are operating in optimal conditions. Maintaining temperature above a certain level may also protect against condensation forming on internal surfaces of the housing. This could help protect electrical components from water damage and also provide a better working environment for operators/landlords.

Furthermore, under normal operating conditions with both doors 12, 14 closed, the one or more fluid movement devices (e.g. the fluid movement device 42 shown in FIG. 4b) and the exhaust control device 48 are operable to maintain an internal pressure within the housing 2 that is greater than an external pressure outside of the housing 2. When one or both doors are open, operation of the one or more fluid movement devices 42 and the exhaust control device 48 to maintain the desired internal pressure may be paused until both doors are closed once more.

Controlling airflow in and out of the housing 2 so that the internal pressure is greater than the external pressure prevents unintended inflow of air through any small gaps that exist in the structure of the housing 2. Therefore, the only air entering the housing 2 (unless one or both doors are opened) is air that enters through air filters within the intake vent arrangement 40. Thus, the housing 2 is protected from unfiltered air.

Also visible in FIG. 5 is the telecommunications antenna 30 positioned in the roof space 32 covered by the radome and connectable to the operator telecommunications equipment.

A further aspect of the housing 2, which is particularly visible in FIGS. 2a, 3 and 4a, is that the plurality of operator equipment cabinets 20, plurality of operator provision panels 22, electrical supply panel 26 and connector channel 50 form a rigid three-dimensional structure extending across an internal dimension of the enclosure 6. This three-dimensional structure acts as a brace for all four walls 4 and thereby rigidifies the enclosure 6 to be robust against external forces, caused by strong crosswinds for example.

This eliminates the need for additional bracing struts within the housing 2 that might otherwise obstruct landlord and/or operator access to the contents of the housing 2.

In use, the housing 2 may be used as a hub for providing a telecommunications network. For example, 4G and/or 5G radios may be connected to the telecommunications antenna 30 to supply 4G and/or 5G connectivity to a local area.

When providing 4G and/or 5G connectivity, telecommunications antennas are emitting radiofrequency electromagnetic fields. Radiation levels associated with these fields are dependent on the effective isotropic radiated power (EIRP) that is supplied to the telecommunications antenna by the associated radios.

Known telecommunications radios installed in public places, such as streets, to boost 4G or 5G connectivity typically provide a low EIRP (e.g. up to 10 W). This means that the amount of radiation produced by the associated antenna is also low, so much so that the level of radiation is essentially negligible. That is, at any range beyond the physical housing of the antenna, the radiation is entirely non-harmful to humans. Furthermore, due to the low power requirements, such radios and antennas are typically installed in largely inaccessible locations, such as on lamp posts or on the sides of buildings and other similar structures.

However, as the demand for high quality 4G and 5G connectivity continues to increase, these low power telecommunications systems are increasingly inadequate, providing very minimal range for the strength of internet connection that is now required by the public in their everyday lives.

On the other hand, large radio towers are capable of providing high quality connectivity while also positioning antennas sufficiently removed from publicly accessible spaces to ensure that the emitted radiation is not harmful to the public. Unfortunately, many locations are ill-suited to benefit from that connectivity, particularly heavily built-up areas with large buildings that interrupt and dilute radio signals.

There is therefore a need for more powerful radios installed locally to provide high quality 4G and 5G connectivity, particularly in built-up areas with high population densities. However, it remains imperative that the public are not exposed to potentially harmful levels of radiation.

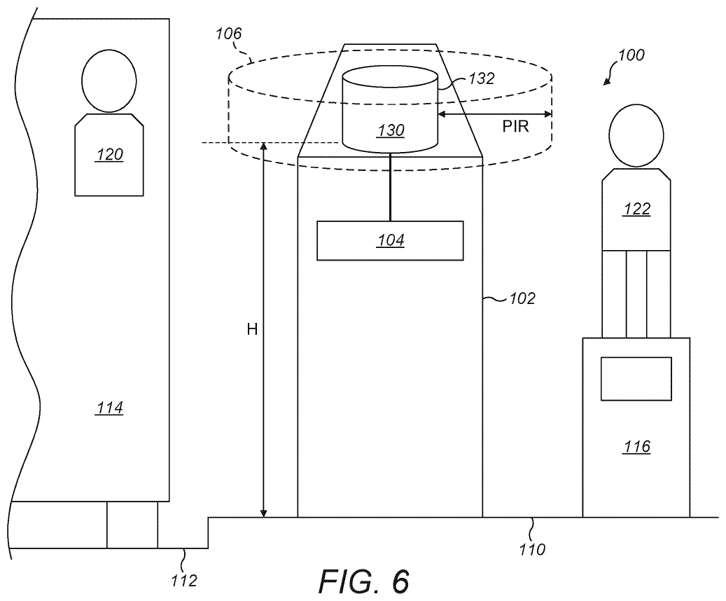

FIG. 6 shows a radio equipment installation 100 (also referred to as an installation 100) for providing a telecommunications network. The installation 100 comprises a radio equipment housing 102 (or housing 102) installed at ground level. In this instance, ground level is the level of a street pavement/sidewalk 110.

In some embodiments, the housing 102 may be configured similarly or identically to the housing 2 shown in FIGS. 1 to 5. In other embodiments, the housing 102 may be configured differently to the housing 2 shown in FIGS. 1 to 5.

In this embodiment, the housing 102 includes a set of radios 104 and a telecommunications antenna 130. The set of radios 104 comprises at least one 4G or 5G radio and a set of connectors for connecting the radios to the telecommunications antenna 130. The set of radios 104 is also configured to be capable of, in use, providing an EIRP of 100 W.

The telecommunications antenna 130 is configured to operate in a plurality of frequency bands and transmit signals from the set of radios 104. Also, the telecommunications antenna 130 comprises a plurality of ports, wherein the set of radios 104 is connected to the telecommunications antenna 130 via a set of ports selected from the plurality of ports.

The installation 100 is configured such that the housing 102 holds the telecommunications antenna 130 a predetermined height H above the ground. In this embodiment, the predetermined height His 2.5 m above ground level. In other embodiments, the predetermined height H may be higher than 2.5 m above ground level.

The installation 100 is also configured such that the housing 102 is located in its environment to provide a physical isolation zone 106 extending radially from an outer surface 132 of the telecommunications antenna 130 by a physical isolation radius PIR.

An antenna provided with an EIRP of 100 W will generate a field of potentially harmful radiation extending radially outward. In reality, the field of radiation extends irregularly with the average extent of potentially harmful radiation extending much less than 1 m, but there may be some spikes in certain directions that stretch as far as 1 m. Accordingly, the International Commission on Non-Ionizing Radiation Protection (ICNIRP) determines that an antenna provided with an EIRP of 100 W should operate with an Exclusion Zone extending 1 m radially outward from the antenna, whereby the Exclusion Zone should not be entered.

Accordingly, in the embodiment shown in FIG. 6, wherein the telecommunications antenna 130 is provided with an EIRP of 100 W, the physical isolation radius PIR equals 1 m. In other words, the housing is located in its environment so that member of the public cannot inadvertently enter a zone extending 1 m radially from the outer surface 132. Further, in this example, the telecommunications antenna 130 is oriented such that the Exclusion Zone and associated physical isolation zone extends horizontally.

In the example shown in FIG. 6, the environment of the housing 102 is a street comprising a road 112 running parallel to the pavement 110. The housing 102 is therefore positioned a suitable distance from the road 112 to ensure that passengers of tall passing vehicles will not enter the physical isolation zone 106. For example, FIG. 6 shows a bus 114 temporarily parked alongside the housing 102. Although a passenger 120 of the bus 114 is occupying a region well above 2.5 m from ground level, the housing 102 is positioned suitably far from the road the passenger 120 is at no risk of inadvertently entering the physical isolation zone 106.

The street shown in FIG. 6 also includes street furniture, specifically a litter bin 116. The housing 102 is located sufficiently far from the litter bin 116 that a pedestrian 122 climbing on top of the litter bin 116 would not inadvertently enter the physical isolation zone 106. (In this example, the pedestrian 122 might be a child playing with friends.)

The set of radios 104 may, for example, comprise a single 4G radio, two 4G radios, a 4G radio and a 5G radio, two 4G radios and a 5G radio, a 4G radio and two 5G radios, just a single 5G radio or two 5G radios.

In examples in which the telecommunications antenna 130 is provided with an EIRP of 100 W, a set of radios comprising just a single 4G radio would be configured so that the 4G radio provides the full 100 W. On the other hand, for a set of radios comprising more than one radio, the EIRP would be shared between them. If both a 4g radio and a 5G radio are included, the EIRP may not be divided evenly. In an example with a set of radios including one of each, the 4G radio may be configured to provide 20 W while the 5G radio provides 80 W. The 5G radio may be prioritised in this way due to the 5G frequency (3400 MHz) not propagating as far as 4G frequencies (e.g. 1800 MHz).

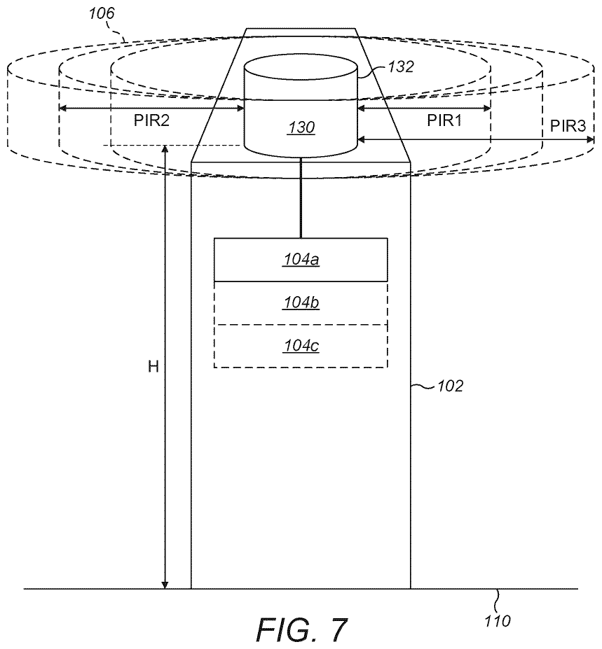

Now referring to FIG. 7, the housing 102 may be fitted with up to three sets of radios 104a, 104b, 104c.

If the housing 102 is installed with just a first set of radios 104a (similarly to the installation 100 shown in FIG. 6), the first set of radios 104 is configured to be capable of, in use, providing an EIRP of 100 W such that the total EIRP provided to the telecommunications antenna 130 is 100 W. The housing 102 may therefore be installed with a physical isolation zone extending with a physical isolation radius PIR1 of 1 m.

However, if the housing 102 is installed with a first set of radios 104a and a second set of radios 104b, both sets of radios 104a, 104b may be configured to be capable of, in use, providing an EIRP of 100 W such that the total EIRP provided to the telecommunications antenna 130 is 200 W.

The higher EIRP results in a larger ICNIRP Exclusion Zone of 1.25 m. Accordingly, the housing 102 may therefore be installed with a physical isolation zone extending with a physical isolation radius PIR2 of 1.25 m.

Furthermore, if the housing 102 is installed with a first set of radios 104a, a second set of radios 104b and a third set of radios 104c, all three sets of radios 104a, 104b, 104c may be configured to be capable of, in use, providing an EIRP of 100 W such that the total EIRP provided to the telecommunications antenna 130 is 300 W.

In this case, the higher EIRP results in a larger ICNIRP Exclusion Zone of 1.5 m. Accordingly, the housing 102 may be installed with a physical isolation zone 106 extending with a physical isolation radius PIR3 of 1.5 m.

The inclusion of two or three sets of radios may be particularly useful as it allows two or three different telecommunications operators to distribute a 4G and/or 5G network from the same housing 102, via the same telecommunications antenna 130. This means that a single structure can be used by multiple telecommunications operators to provide high quality 4G/5G connectivity to their customers. Consequently, the number of telecommunication structures installed in streets and other public places may be reduced.

Especially in instances where multiple telecommunications operators are using the same housing 102, it may be particularly advantageous if the housing 102 is configured similarly to the housing 2 shown in FIGS. 1-5. The operator side of the housing 2 is optimally arranged for safely, securely and neatly storing telecommunications equipment belonging to separate parties.

To provide for suitable connection between the/each set of radios 104a, 104b, 104c and the telecommunications antenna 130, each set of ports comprises at least eight ports connected to an associated set of radios 104a, 104b, 104c. For example, each set of ports may comprise four 4G ports and four 5G ports. If a set of radios comprises more than one of either a 4G radio or a 5G radio, combiners may be used to facilitate suitable connection with the relevant ports.

Accordingly, as the housing 102 may be fitted with up to three sets of radios 104a, 104b, 104c, the telecommunications antenna 130 comprises at least three sets of ports, corresponding to at least 24 ports in total.

In examples beyond those shown in FIGS. 6 and 7, a single set of radios may be configured to be capable of, in use, providing an EIRP of more than 100 W, such as 200 W or 300 W. In such examples, the physical isolation zone 106 would be expanded very similarly to a housing comprising more than one set of radios. That is, if a single set of radios provides an EIRP of 200 W, the housing would be installed with physical isolation zone 106 having a physical isolation radius of 1.25 m. Meanwhile, if a single set of radios provides an EIRP of 300 W, the housing would be installed with physical isolation zone having a physical isolation radius of 1.5 m.

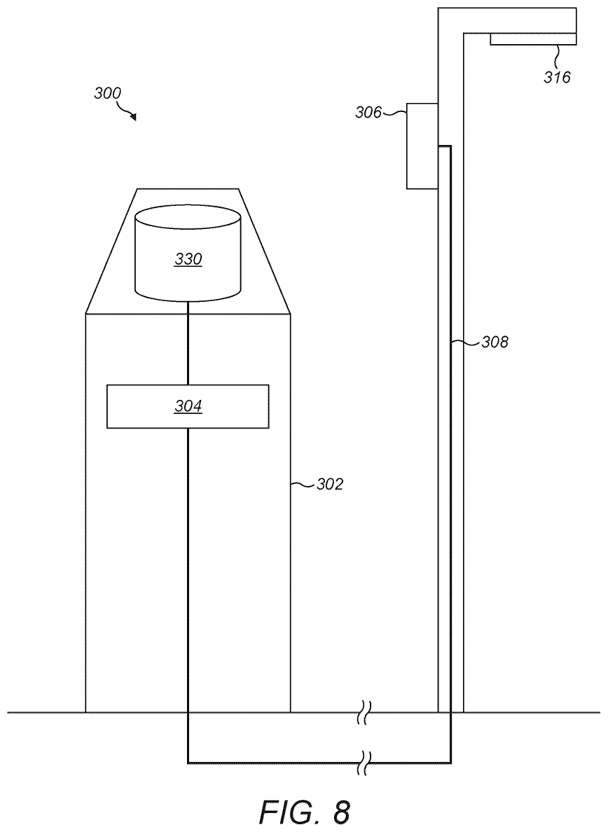

FIG. 8 shows a radio equipment assembly 300 (also referred to as an assembly 300). The assembly 300 comprises a radio equipment housing 302 (or housing 302) installed at ground level.

The housing 302 includes at least one set of radios 304 and a telecommunications antenna 330. The, or each, set of radios comprising at least one 4G or 5G radio and a set of connectors for connecting the radios to the telecommunications antenna 330. The telecommunications antenna 330 is configured to operate in a plurality of frequency bands and simultaneously transmit signals from a plurality of sets of radios. The telecommunications antenna 330 also comprises a plurality of ports, wherein the at least one set of radios is connected to the telecommunications antenna via a respective at least one set of ports of the plurality of ports.

In some embodiments, the housing 302 may be configured similarly or identically to the housing 2 shown in FIGS. 1 to 5. In other embodiments, the housing 102 may be configured differently to the housing 2 shown in FIGS. 1 to 5. Furthermore, the housing 302 may be installed as part of an installation similar or identical to the installation 100 shown in FIG. 6.

The assembly 300 further comprises at least one radio unit 306 installed remotely to the radio equipment housing 302, wherein the at least one radio unit 306 is connected to the housing 302 via a cabled connection 308 to receive data, power or both from the housing 302. The radio unit 306 may also supply data to the housing 302 via the cabled connection 308.

In this example, the at least one radio unit is mounted on street furniture, specifically a lamppost 316. Other suitable street or park furniture might include road signs, tourist information signs, bus or tram stop shelters, gazebos or pagodas. Alternatively, a radio unit may be mounted on larger structures such as retail kiosks, buildings and bridges.

As mentioned above, the cabled connection 308 may facilitate transfer of date from the housing 302 to the radio unit 306 and/or from the radio unit 306 to the housing. Accordingly, 4G and/or 5G connectivity may be provided by both the telecommunications antenna 330 and the radio unit 306. Thus coverage may be expanded compared to the housing 302 operating independently and certainly compared to known telecommunications devices currently in deployment that operate independently of one another.

The cabled connection 308 may additionally, or alternatively, facilitate supply of power from the housing 302 to the radio unit 306. Although radio units suitable for incorporation in a radio equipment assembly (such as the assembly 300 shown in FIG. 8) are well known, a common hurdle in deploying them successfully is a lack of access to a suitable power supply. The assembly 300 overcomes this problem as the housing 302 may comprise a distribution substation capable of transforming high voltage alternating current (AC) to the low voltage direct current (DC) required by radio units. Accordingly, the cabled connection 308 facilitates supply of low voltage DC to radio unit 306.

The cabled connection 308 may comprise at least one hybrid fibre optic cable extending from the housing 302 to the radio unit 306 and configured to supply both data and power from the housing 302 to the radio unit 306. The radio unit 306 may also supply data to the housing 302 via the hybrid fibre optic cable 308. Thus, only a single cable requires installation between the housing 302 and the radio unit 306. Simplification of the installation process can be of vital importance, particularly in densely populated areas where road closures can be very costly.

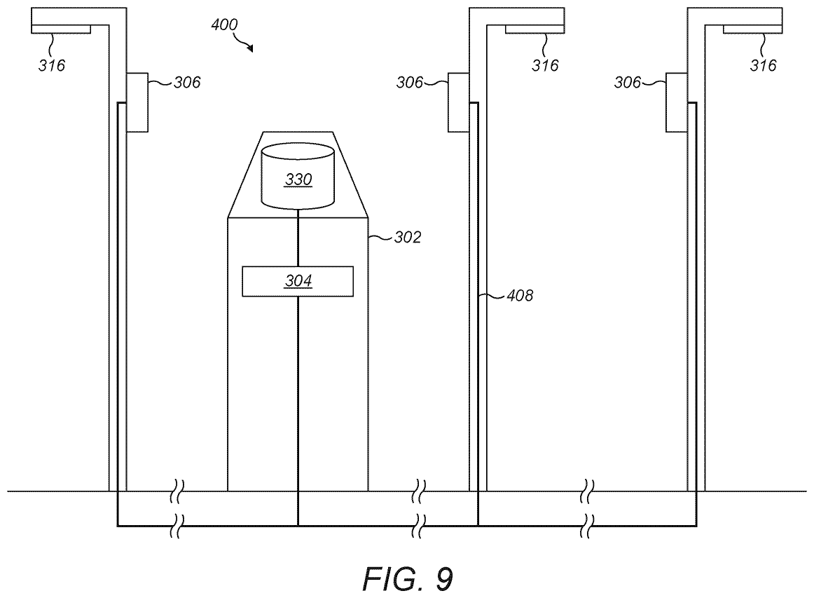

FIG. 9 shows a radio equipment assembly 400 (also referred to as an assembly 400). The assembly 400 is the same as the assembly 300 shown in FIG. 8 except that it comprises a plurality of radio units 306, each mounted on a respective lamppost 306. Accordingly, the cabled connection 408 connects the housing 302 to each of the radio units 306.

The housing 302 may be considered as a hub providing high quality 4G and/or 5G connectivity over a wide area and with strong in-building penetration, while the plurality of remote radio units 306 act as spokes extending the reach of telecommunications network to key areas beyond the scope of the housing 302 at a relatively low cost, albeit with lower power and capacity for in-building penetration.

This may be useful in a variety of different situations. For example, a housing 302 may be installed in a central location of a town or city that often represents a gathering point for resulting in high densities of people requiring 4G/5G connectivity, such as a town square, for example. Connected radio units 30 may be strategically placed along nearby streets and roads spreading from the central location, particularly those that experience heavy traffic or footfall and might therefore require a boost in connectivity.

Issues with 4G/5G connectivity often occur when a particular event, such as a music concert or sports event, is attended by a large number of people (e.g. tens of thousands) the majority of whom desire access to a strong internet connection with their mobile phones. Accordingly, in another example, a housing 302 may be installed outside an arena or stadium that regularly hosts such events. Connected radio units 306 may be positioned along the routes that people tend to travel along when arriving at or departing from the venue.

In some examples, the housing 302 is configured similarly to the housing 102 shown in FIG. 7 in that the housing 302 may be fitted with up to three sets of radios. Each set of radios may belong to a respective telecommunications operator providing wireless communication and high-speed data connectivity to respective customers. Thus, the housing 302 is further configured similarly to the housing 2 shown in FIGS. 1 to 5 so that each operator has its own space within the housing 302 to store its set of radios and associated equipment.

In certain examples, a remote radio unit 306 may be configured for use by a single operator. In such examples, the radio unit 306 may be configured very similarly to the respective operator's set of radios 304 stored in the housing 302. This provides each operator with greater control over its telecommunications equipment.

In other examples, a remote radio unit 306 may be configured to be shared by all operators using the associated housing 302. This enables network connectivity to be extended while minimising duplication of equipment and reducing overall cost.

With reference to FIGS. 6 and 8, a method of installing radio equipment including at least one set of radios 104/304 and a telecommunications antenna 130/330 may comprise housing the at least one set of radios 104/304 and the telecommunications antenna 130/330 within a radio equipment housing 102/302. The method may also comprise installing the radio equipment housing 102/302 at ground level such that the radio equipment housing 102/302 holds the telecommunications antenna 130/330 at least 2.5 m above ground level and such that the radio equipment housing 102/302 is located in its environment to provide a physical isolation zone 106 extending radially from an outer surface of the telecommunications antenna by at least 1 m.

Installing the radio equipment housing 102/302 may comprise locating the radio equipment housing 102/302 in its environment to provide a physical isolation zone 106 extending radially from an outer surface of the telecommunications antenna by at least 1.25 m; or by at least 1.5 m.

The method may further comprise installing at least one radio unit 306 remotely to the radio equipment housing 102/302. Installing the at least one radio unit 306 may comprise installing the at least one radio unit 306 on street furniture 316.

In additional embodiments, the method may further comprise installing at least one hybrid fibre optic cable 308 connecting the radio equipment housing 102/302 to the at least one radio unit 306. The at least one hybrid fibre optic cable 308 may be configured to supply data and power from the radio equipment housing 102/302 to the at least one radio unit 306.

The method may also comprise housing at least one base band unit within the radio equipment housing 102/302.

1. A radio equipment housing for electronic communications devices, comprising:
one or more wall portions defining an enclosure having a landlord entryway and an operator entryway, each entryway having a door arranged to be closable over the respective entryway;
a radome arranged to cover the enclosure;
a plurality of operator equipment cabinets, individually accessible via the operator entryway and arranged within a first volume of the enclosure, each cabinet configured to receive operator telecommunications equipment therein;
a plurality of operator provision panels, accessible via the operator entryway and arranged within a second volume of the enclosure, each provision panel holding one or more provision ports for providing electrical connections for operator telecommunications equipment housed within a respective adjacent operator equipment cabinet;
an electrical supply panel, accessible via the landlord entryway and arranged within a third volume of the enclosure, for supplying power to the provision ports of the provision panels; and,
at least one telecommunications antenna positioned in a roof space covered by the radome and connectable to the operator telecommunications equipment.

2. A radio equipment housing claim 1, wherein the operator equipment cabinets are vertically spaced in a stacked arrangement within the first volume.

3. A radio equipment housing according to claim 2, wherein the operator provision panels are vertically spaced in a stacked arrangement within the second volume, each operator provision panel arranged in substantially the same plane as the respective adjacent operator equipment cabinet.

4. A radio equipment housing according to claim 2, wherein the electrical supply panel comprises a plurality of operator supply regions, each operator supply region configured to supply power to a respective provision panel.

5. A radio equipment housing according to claim 1, further comprising one or more operator closures, each operator closure arranged to be independently closable over a specific operator equipment cabinet, a specific operator provision panel or both a specific operator equipment cabinet and its respective operator provision panel.

6. A radio equipment housing according to claim 5, wherein the, or each, operator closure is independently lockable and unlockable.

7. A radio equipment housing according to claim 1, wherein at least one of the one or more wall portions comprises an intake vent arrangement.

8. A radio equipment housing according to claim 7, wherein the intake vent arrangement comprises a filter assembly for removably receiving one or more air filters.

9. A radio equipment housing according to claim 7, wherein:
each operator equipment cabinet comprises an air inlet and an air outlet;
the radio equipment housing comprises one or more fluid movement devices arranged proximally to one or more air inlets or air outlets and operable to move air through the respective one or more operator equipment cabinets; and
the air inlet and air outlet are arranged such that operation of the one or more fluid movement devices generates a crossflow of air through the respective one or more operator equipment cabinets.

10. A radio equipment housing according to claim 9, wherein each air inlet of the equipment cabinet is arranged proximally to the intake vent arrangement.

11. A radio equipment housing according to claim 9, further comprising an exhaust vent arrangement allowing air that has travelled through one or more operator equipment cabinets to exit the housing.

12. A radio equipment housing according to claim 11, further comprising an exhaust control device coupled to the exhaust vent arrangement and configured to control the rate that air exits the radio equipment housing.

13. A radio equipment housing according to claim 12, wherein the one or more fluid movement devices and the exhaust control device are operable to maintain an internal pressure within the radio equipment housing that is greater than an external pressure outside of the radio equipment housing.

14. A radio equipment housing according to claim 1, wherein the radio equipment housing further comprises a connector channel, arranged within a fourth volume of the enclosure, providing space for one or more connectors to extend at least partially from the plurality of operator equipment cabinets and/or the plurality of operator provision panels to, at least, the antenna, the connector channel comprising a channel accessway suitable for access of an operator via the operator entryway.

15. A radio equipment housing according to claim 14, wherein one or more of the plurality of operator equipment cabinets, plurality of operator provision panels, electrical supply panel and connector channel form a rigid three-dimensional structure extending across an internal dimension of the enclosure, thereby rigidifying the enclosure.

16. A radio equipment housing according to claim 1, wherein the landlord entryway and the operator entryway are arranged on substantially opposing sides of the enclosure.

17. A radio equipment housing according to claim 1, wherein the one or more wall portions comprise four wall portions including a first wall portion, comprising the landlord entryway, and a second wall portion, comprising the operator entryway, arranged substantially opposite the first wall portion.

18. A radio equipment housing according to claim 1, wherein the roof space is accessible via the landlord entryway, operator entryway or both.

19. A radio equipment housing for electronics communications devices, comprising:
four wall portions defining an enclosure having a landlord entryway and an operator entryway located substantially opposite to the landlord entryway, each entryway having a door arranged to be closable over the respective entryway;
a radome arranged to cover the enclosure;
a plurality of vertically spaced operator equipment cabinets, individually accessible via the operator entryway and arranged within a first volume of the enclosure, each cabinet configured to receive operator telecommunications equipment therein;
a plurality of vertically spaced operator provision panels, accessible via the operator entryway and arranged within a second volume of the enclosure, each provision panel holding one or more provision ports for providing electrical connections for operator telecommunications equipment housed within a respective adjacent operator equipment cabinet;
an electrical supply panel, accessible via the landlord entryway and arranged within a third volume of the enclosure, for supplying power to the provision ports of the provision panels; and,
at least one telecommunications antenna positioned in a roof space covered by the radome and connectable to the operator telecommunications equipment.

20-43. (canceled)
